(19) United States
(12) Patent Application Publication
(10) Pub. No.: US 2025/0212453 A1
(43) Pub. Date: Jun. 26, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Yasuhiro SHIMIZU, Ibo Hyogo (JP)

(21) Appl. No.: 19/076,168

(22) Filed: Mar. 11, 2025

Related U.S. Application Data
(63) Continuation of application No. PCT/JP2024/007049, filed on Feb. 27, 2024.

(30) Foreign Application Priority Data
Jul. 11, 2023 (JP) 2023-113965

(51) Int. Cl. H10D 30/66; H10D 62/13; H10D 64/23; H10D 64/60

(52) U.S. Cl. CPC H10D 30/66; H10D 62/154; H10D 62/155; H10D 64/2527; H10D 64/60

(57) ABSTRACT

A semiconductor device according to an embodiment includes: a first electrode; a second electrode opposing the first electrode in a first direction; a semiconductor part provided between the first electrode and the second electrode; a metal silicide layer provided between the second electrode and the semiconductor part; and a metal layer provided between the metal silicide layer and the second electrode. The metal silicide layer includes a recess recessed toward the semiconductor part. The metal layer contacts a bottom surface and a side surface of the recess.

### CROSS-REFERENCE TO RELATED APPLICATIONS

This application is based upon and claims the benefit of priority from Japanese Patent Application No. 2023-113965, filed on Jul. 11, 2023 and PCT Application No. PCT/JP2024/007049, filed on Feb. 27, 2024; the entire contents of which are incorporated herein by reference.

### FIELD

Embodiments of the present invention relate to a semiconductor device.

### BACKGROUND

In a power semiconductor device such as a MOSFET (Metal Oxide Semiconductor Field Effect Transistor), the structure has been known in which a p⁺-type semiconductor region and an n⁺-type semiconductor region are both provided on a lower side of a source electrode. Further, in this structure, a metal silicide layer and a metal layer may be provided between the source electrode and the aforementioned semiconductor regions.

In a power semiconductor device as described above, when current in a reverse direction flows between a drain electrode and the source electrode, a difference in the coefficient of thermal expansion between the metal silicide layer and the metal layer causes a thermal stress. When the thermal stress decreases adhesion between the metal silicide layer and the metal layer, metal peeling and metal cracks are more likely to occur. As a result, reliability could be degraded.

### BRIEF DESCRIPTION OF THE DRAWINGS

FIG. 1 is a cross-sectional view of a semiconductor device according to a first embodiment cut in a perpendicular direction;

FIG. 2 is a perspective view showing the structure of a main part of a semiconductor device 1 according to the first embodiment;

FIG. 3 is a cross-sectional view of a semiconductor device according to a comparative example cut in a perpendicular direction;

FIG. 4 is a perspective view showing the structure of a main part of the semiconductor device according to the comparative example;

FIG. 5 is a cross-sectional view of a semiconductor device according to a second embodiment cut in a perpendicular direction;

FIG. 6 is a perspective view showing the structure of a main part of the semiconductor device according to the second embodiment; and

FIG. 7 is a perspective view showing the structure of a main part of a semiconductor device according to a third embodiment.

### DETAILED DESCRIPTION

Embodiments will now be explained with reference to the accompanying drawings. The present invention is not limited to the embodiments.

A semiconductor device according to an embodiment includes: a first electrode; a second electrode opposing the first electrode in a first direction; a semiconductor part provided between the first electrode and the second electrode; a metal silicide layer provided between the second electrode and the semiconductor part; and a metal layer provided between the metal silicide layer and the second electrode. The metal silicide layer includes a recess recessed toward the semiconductor part. The metal layer contacts a bottom surface and a side surface of the recess.

### First Embodiment

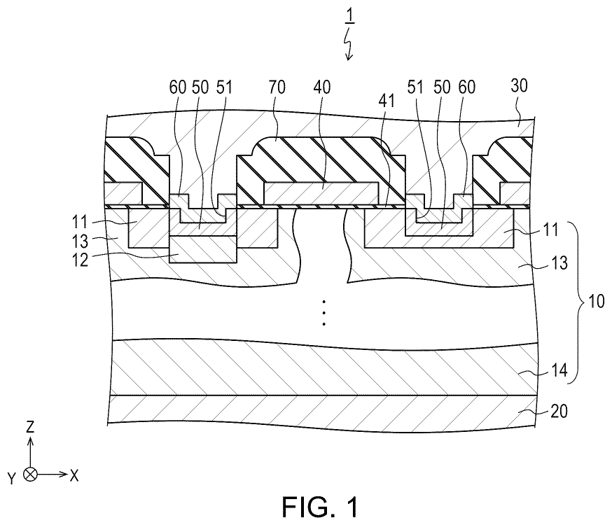

FIG. 1 is a cross-sectional view of a semiconductor device according to a first embodiment cut in a perpendicular direction. A semiconductor device 1 according to the present embodiment is a MOSFET in a planar gate structure. In the following descriptions, the arrangement and the configuration of each part of the semiconductor device are described using an X-axis, a Y-axis, and a Z-axis shown in each drawing in some cases. The X-axis, the Y-axis, and the Z-axis are orthogonal to each other and represent an X-direction (second direction), a Y-direction (third direction), and a Z-direction (first direction), respectively. Further, descriptions will be made referring to the Z-direction as an upper side and the opposite direction as a lower side in some cases. In the present embodiment, the X-direction and the Y-direction represent in-plane directions parallel to the semiconductor device 1 according to the present embodiment, and the Z-direction represents an out-of-plane direction orthogonal to the semiconductor device 1.

Further, notation of p, p⁺ means that the p-type impurity concentration increases in this order. Further, notation of n⁻, n⁺ means that the n-type impurity concentration increases in this order.

An impurity concentration can be measured by, for example, a SIMS (Secondary Ion Mass Spectrometry). Further, a relative level in the impurity concentration can also be determined, for example, based on the level in a carrier concentration obtained by an SCM (Scanning Capacitance Microscopy). Furthermore, a distance such as a depth of the semiconductor region can be obtained by, for example, the SIMS.

The semiconductor device 1 according to the present embodiment includes a semiconductor part 10, a drain electrode 20, a source electrode 30, a gate electrode 40, a metal silicide layer 50, and a metal layer 60. The drain electrode 20 and the source electrode 30 correspond to a first electrode and a second electrode, respectively.

As shown in FIG. 1, the semiconductor part 10 includes an n⁺-type semiconductor region 11, a p⁺-type semiconductor region 12, a p-type semiconductor region 13, and an n⁻-type semiconductor region 14. The n⁺-type semiconductor region 11 corresponds to a first semiconductor region. The p⁺-type semiconductor region 12 corresponds to a second semiconductor region. The p-type semiconductor region 13 corresponds to a third semiconductor region.

The n⁺-type semiconductor region 11 contacts the metal silicide layer 50 on its upper surface or side surface. The n⁺-type semiconductor region 11 is electrically connected to the source electrode 30 via the metal silicide layer 50 and the metal layer 60. The n⁺-type semiconductor region 11 can be formed by, for example, ion implantation of an n-type impurity with a high concentration from a surface of the semiconductor part 10.

The p⁺-type semiconductor region 12 contacts the metal silicide layer 50 on its upper surface. Further, the p⁺-type semiconductor region 12 is electrically connected to the source electrode 30 via the metal silicide layer 50 and the metal layer 60. The p⁺-type semiconductor region 12 can be formed by, for example, ion implantation of a p-type impurity with a high concentration from the surface of the semiconductor part 10.

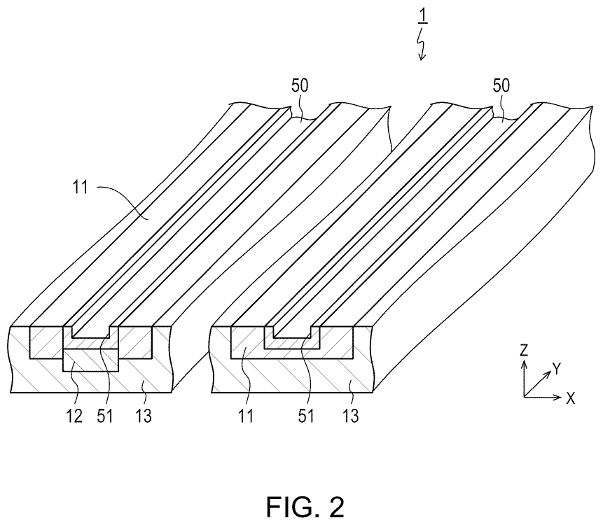

Here, with reference to FIG. 2, the layout of the n⁺-type semiconductor region 11 and the p⁺-type semiconductor region 12 will be described.

FIG. 2 is a perspective view showing the structure of a main part of the semiconductor device 1 according to the first embodiment. As shown in FIG. 2, the n⁺-type semiconductor region 11 and the p⁺-type semiconductor region 12 are arranged side-by-side along the X-direction. Further, the n⁺-type semiconductor regions 11 and the p⁺-type semiconductor regions 12 are adjacently arranged alternately along the Y-direction.

The p-type semiconductor region 13 contacts each semiconductor region so as to surround the n⁺-type semiconductor region 11 and the p⁺-type semiconductor region 12. The p-type semiconductor region 13 can be formed by, for example, ion implantation of a p-type impurity with a low concentration from the surface of the semiconductor part 10.

Returning to FIG. 1, the n⁻-type semiconductor region 14 is a drift region that is arranged on a lowermost layer of the semiconductor part 10. The n⁻-type semiconductor region 14 is composed of, for example, epitaxially grown SiC (silicon carbide).

The n⁻-type semiconductor region 14 is depleted by a drain voltage applied between the drain electrode 20 and the source electrode 30 when the semiconductor device 1 is in an off-state. Therefore, the n⁻-type semiconductor region 14 is designed in thickness so as to satisfy predetermined voltage withstand conditions.

Note that in the semiconductor part 10, various semiconductor layers may be formed between the p-type semiconductor region 13 and the n⁻-type semiconductor region 14. Further, although FIG. 1 and FIG. 2 illustrate nothing in a region between the two p-type semiconductor regions 13 arranged side-by-side along the X-direction, the region may be, for example, a Schottky Barrier Diode region.

The drain electrode 20 is provided on a back surface of the n⁻-type semiconductor region 14. The source electrode 30 is arranged opposing the drain electrode 20 in the Z-direction across the semiconductor part 10. The source electrode 30 is electrically insulated from the gate electrode 40 via an inter-layer dielectric 70. The drain electrode 20 and the source electrode 30 can be formed by, for example, using metal such as aluminum. Further, the inter-layer dielectric 70 is, for example, a silicon oxide film (SiO₂).

The gate electrode 40 opposes the p-type semiconductor region 13 via a gate dielectric 41. The gate electrode 40 can be formed by, for example, using polysilicon. Further, the gate dielectric 41 is, for example, a silicon oxide film (SiO₂). Note that in the present embodiment, the gate electrode 40 is in a planar gate type, but may be in a trench gate type.

The metal silicide layer 50 is provided on the n⁺-type semiconductor region 11. Further, the metal silicide layer 50 is also provided on the p⁺-type semiconductor region 12. The metal silicide layer 50 includes nickel silicon (NiSi).

In forming the metal silicide layer 50, first, a silicon film is formed on the n⁺-type semiconductor region 11 and the p⁺-type semiconductor region 12. Subsequently, a metal film composed of nickel or the like is formed on the silicon film by, for example, sputtering. Thereafter, silicon and metal are reacted with each other through annealing or the like to form the metal silicide layer 50. Here, with reference to FIG. 2, the structure of the metal silicide layer 50 will be described.

As shown in FIG. 2, the metal silicide layer 50 includes a recess 51 recessed toward the semiconductor part 10 (n⁺-type semiconductor region 11, p⁺-type semiconductor region 12). The recess 51 is formed in a groove shape continuously extending along the Y-direction. Note that in the n⁺-type semiconductor region 11 and the p⁺-type semiconductor region 12, regions contacting the metal silicide layer 25 50 are recessed along a shape of an outer periphery surface of the recess 51.

Returning to FIG. 1, the metal layer 60 contacts each of an inner side surface and a bottom surface of the aforementioned recess 51. That is, a shape of a bottom surface of the metal layer 60 is a projection shape so as to closely adhere to an inner periphery surface of the recess 51 of the metal silicide layer 50. Further, an upper surface of the metal layer 60 is recessed toward the metal silicide layer 50. Therefore, a bottom surface of the source electrode 30 contacting the metal layer 60 is in a projection shape along the recess of the metal layer 60. The metal layer 60 can be formed by vapor deposition of metal such as titanium.

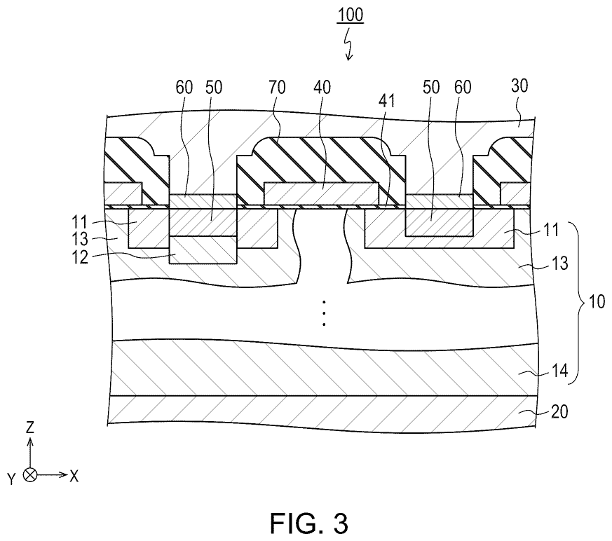

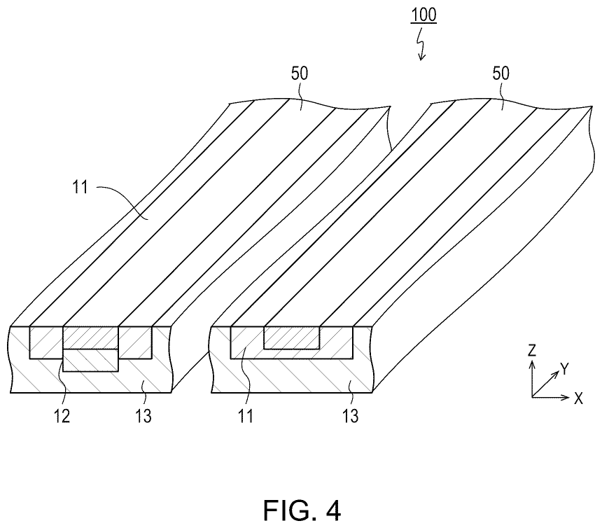

Here, with reference to FIG. 3 and FIG. 4, a comparative example to be compared with the present embodiment will be described.

FIG. 3 is a cross-sectional view of a semiconductor device according to a comparative example cut in a perpendicular direction. FIG. 4 is a perspective view showing the structure of a main part of the semiconductor device according to the comparative example. In FIG. 3 and FIG. 4, for the same constituent elements as those of the aforementioned semiconductor device 1, the same reference signs are assigned and the detailed descriptions will be omitted.

As shown in FIG. 4, in a semiconductor device 100 according to the present comparative example, the metal silicide layer 50 is formed in a flat plate shape. Therefore, as shown in FIG. 4, only an upper surface of the metal silicide layer 50 is a surface contacting the metal layer 60.

In the semiconductor device 100 configured as described above, for example, when current in a reverse direction from the source electrode 30 toward the drain electrode 20 flows, a large current is concentrated particularly in the p⁺-type semiconductor region 12. Therefore, the p⁺-type semiconductor region 12 generates heat. The generated heat is transmitted to the metal silicide layer 50 contacting the p⁺-type semiconductor region 12 and the metal layer 60 contacting the metal silicide layer 50.

The coefficient of thermal expansion differs between the metal silicide layer 50 contacting the p⁺-type semiconductor region 12 and the metal layer 60. Therefore, a thermal stress resulted from the difference in the coefficient of thermal expansion is generated at an interface between the metal silicide layer 50 and the metal layer 60. This thermal stress could decrease adhesion at the interface between the metal silicide layer 50 and the metal layer 60. When the adhesion decreases, metal peeling of the metal layer 60 from the metal silicide layer 50 and metal crack of the metal layer 60 being cracked are more likely to occur.

Thus, in the present embodiment, a recess is formed by etching or the like of the n⁺-type semiconductor region 11 or the p⁺-type semiconductor region 12 and the recess 51 is formed by sputtering a metal film composed of nickel or the like. Further, the metal layer 60 is formed so as to closely adhere to the inner side surface and the bottom surface of the recess 51. As a result, the adhesion between the metal silicide layer 50 and the metal layer 60 is enhanced due to an anchoring effect. Accordingly, metal peeling and metal crack of the metal layer 60 are less likely to occur to thus improve the reliability.

Further, in the present embodiment, the source electrode 30 includes aluminum. Aluminum is a relatively flexible metal. Therefore, the source electrode 30 enters up to the recess 51 side, thereby functioning as a cushion to mitigate the thermal stress due to the difference in the coefficient of thermal expansion between the metal silicide layer 50 and the metal layer 60. As a result, metal peeling and metal crack of the metal layer 60 are further less likely to occur to thus further improve the reliability.

Note that in the semiconductor device 1 according to the present embodiment, when a predetermined voltage is applied between the drain electrode 20 and the source electrode 30, a channel is formed within the p-type semiconductor region 13. In this manner, current in the forward direction from the drain electrode 20 toward the source electrode 30 flows. At this time, when the current value is large, the thermal stress is generated at the interface between the metal silicide layer 50 contacting the n⁺-type semiconductor region 11 and the metal layer 60 contacting the metal silicide layer 50. Therefore, a decrease in the adhesion between the two layers is concerned.

However, in the present embodiment, the recess 51 is formed not only on the metal silicide layer 50 contacting the p⁺-type semiconductor region 12, but also on the metal silicide layer 50 contacting the n⁺-type semiconductor region 11. As a result, the adhesion between the metal silicide layer 50 contacting the n⁺-type semiconductor region 11 and the metal layer 60 contacting the metal silicide layer 50 is enhanced due to the anchoring effect. Accordingly, metal peeling and metal crack are less likely to occur not only on the p⁺-type semiconductor region 12 side, but also on the n⁺-type semiconductor region 11 side to thus further enable the reliability to be improved.

### Second Embodiment

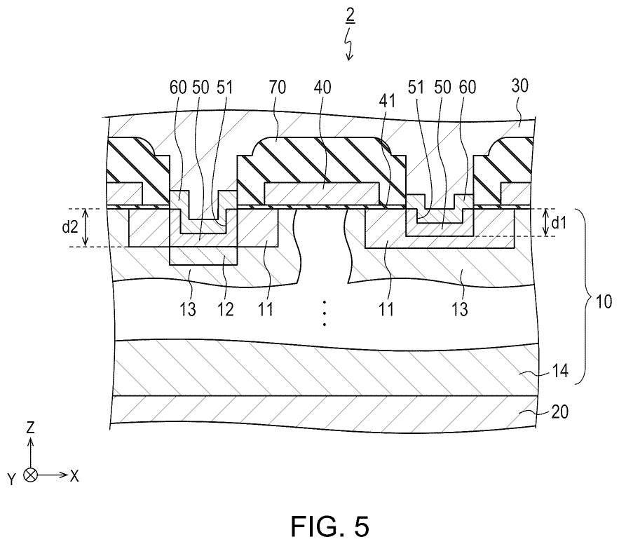

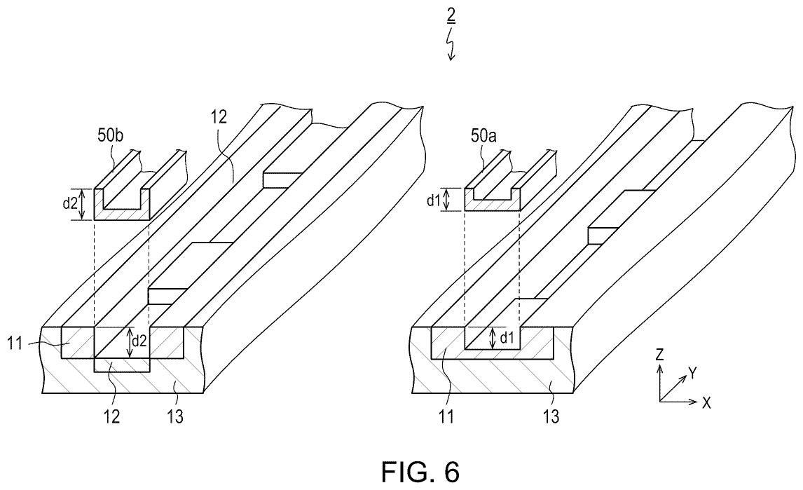

FIG. 5 is a cross-sectional view of a semiconductor device according to a second embodiment cut in a perpendicular direction. FIG. 6 is a perspective view showing the structure of a main part of the semiconductor device according to the second embodiment. In FIG. 5 and FIG. 6, for the same constituent elements as those of the aforementioned first embodiment, the same reference signs are assigned and the detailed descriptions will be omitted.

A semiconductor device 2 according to the present embodiment differs from the first embodiment in the shape of the metal silicide layer 50. In the metal silicide layer 50 according to the aforementioned first embodiment, the depth from the surface of the semiconductor part 10 to a lower end of the metal silicide layer 50 is the same between a first portion 50a contacting the n⁺-type semiconductor region 11 and a second portion 50b contacting the p⁺-type semiconductor region 12.

Meanwhile, in the metal silicide layer 50 according to the present embodiment, as shown in FIG. 5 and FIG. 6, the depth from the surface of the semiconductor part 10 to the lower end of the metal silicide layer 50 differs between the first portion 50a and the second portion 50b. Specifically, a depth d2 of the second portion 50b is greater than a depth d1 of the first portion 50a. As the aforementioned depth increases, the anchoring effect between the metal silicide layer 50 and the metal layer 60 increases.

To form the metal silicide layer 50 including the first portion 50a and the second portion 50b, in the present embodiment, as shown in FIG. 6, the n⁺-type semiconductor region 11 is etched until reaching the depth d1 and the p⁺-type semiconductor region 12 is etched until reaching the depth d2.

In the semiconductor device 2 according to the present embodiment, as with the first embodiment, when current in the reverse direction flows between the drain electrode 20 and the source electrode 30, the current is concentrated in the p⁺-type semiconductor region 12. Therefore, the thermal stress could be generated at the interface between the metal silicide layer 50 and the metal layer 60.

However, in the metal silicide layer 50 according to the present embodiment, the depth d2 of the second portion 50b contacting the p⁺-type semiconductor region 12 is greater than the depth d1 of the first portion 50a contacting the n⁺-type semiconductor region 11. Therefore, the anchoring effect of the second portion 50b increases as compared to the first embodiment. As a result, the adhesion between the metal silicide layer 50 and the metal layer 60 is enhanced. Accordingly, the reliability can be further improved.

Note that in the present embodiment, the depth d2 of the second portion 50b is greater than the depth d1 of the first portion 50a, but the magnitude relation of depth may be changed in accordance with the magnitude of the current, as appropriate. For example, when a large current flows in the forward direction between the drain electrode 20 and the source electrode 30, the adhesion between the metal silicide layer 50 and the metal layer 60 is likely to decrease.

In the case as described above, the depth d1 of the first portion 50a simply needs to be increased as compared to the depth d2 of the second portion 50b. In this manner, the adhesion between the metal silicide layer 50 and the metal layer 60 is enhanced. Accordingly, the reliability can be further improved.

### Third Embodiment

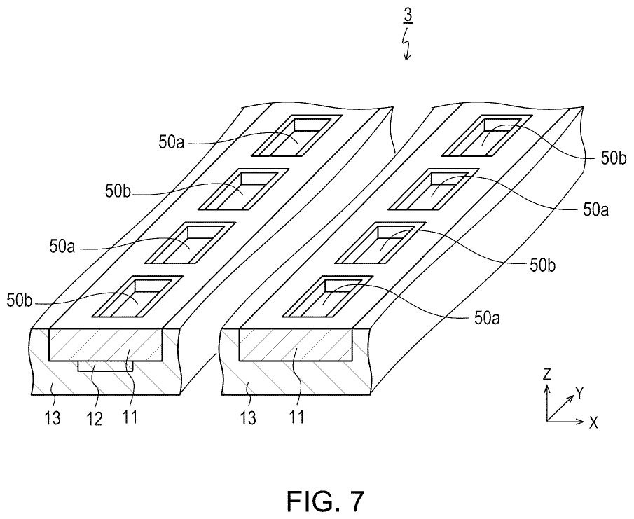

FIG. 7 is a perspective view showing the structure of a main part of a semiconductor device according to a third embodiment. In FIG. 7, for the same constituent elements as those of the aforementioned first embodiment, the same reference signs are assigned and the detailed descriptions will be omitted. Note that since the cross-sectional structure of a semiconductor device 3 according to the present embodiment is the same as that of the first embodiment shown in FIG. 1, the illustration and description will be omitted.

The semiconductor device 3 according to the present embodiment differs from the first embodiment in the structure of the metal silicide layer 50. Specifically, the first portions 50a contacting the n⁺-type semiconductor region 11 and the second portions 50b contacting the p⁺-type semiconductor region 12 are arranged in a lattice form along the X-direction and the Y-direction. In other words, the first portions 50a and the second portions 50b are discontinuously alternately arranged along the X-direction and the Y-direction.

The first portions 50a are each formed in a recessed shape recessed toward the n⁺-type semiconductor region 11 and the second portions 50b are each formed in a recessed shape recessed toward the p⁺-type semiconductor region 12. Further, the metal layer 60 is filled without a gap along the recessed shape of each of the first portions 50a and the second portions 50b. Therefore, the adhesion between the metal silicide layer 50 and the metal layer 60 is enhanced due to the anchoring effect. As a result, even when current in the forward direction and the reverse direction flows between the drain electrode 20 and the source electrode 30, defects such as peeling and crack of the metal layer 60 are less likely to occur.

Accordingly, according to the present embodiment, the reliability can be improved as with the first embodiment.

Further, in the present embodiment, as shown in FIG. 7, the n⁺-type semiconductor region 11 is interposed between the first portions 50a and the second portions 50b that are arranged along the Y-direction. Therefore, the area of the n⁺-type semiconductor region 11 enlarges as compared to the first embodiment. As a result, the on-resistance can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a first electrode;
a second electrode opposing the first electrode in a first direction;
a semiconductor part provided between the first electrode and the second electrode;
a metal silicide layer provided between the second electrode and the semiconductor part; and
a metal layer provided between the metal silicide layer and the second electrode,
wherein
the metal silicide layer includes a recess recessed toward the semiconductor part, and
the metal layer contacts a bottom surface and a side surface of the recess.

2. The semiconductor device according to claim 1, wherein the semiconductor part comprises a first semiconductor region of a first conductive type contacting the metal silicide layer.

3. The semiconductor device according to claim 2, wherein
the semiconductor part comprises a second semiconductor region of a second conductive type, and
the metal silicide layer comprises a first portion contacting the first semiconductor region and a second portion contacting the second semiconductor region.

4. The semiconductor device according to claim 3, wherein the first semiconductor region and the second semiconductor region are arranged side-by-side along a second direction orthogonal to the first direction.

5. The semiconductor device according to claim 4, wherein the first semiconductor region and the second semiconductor region are adjacently arranged alternately along a third direction orthogonal to the first direction and the second direction.

6. The semiconductor device according to claim 5, wherein the recess is in a groove shape continuously extending in the third direction.

7. The semiconductor device according to claim 3, wherein a depth from a surface of the semiconductor part to a lower end of the metal silicide layer differs between the first portion and the second portion.

8. The semiconductor device according to claim 5, wherein the first portion and the second portion are arranged in a lattice form along the second direction and the third direction.

9. The semiconductor device according to claim 3, further comprising:
a third semiconductor region of the second conductive type contacting the first semiconductor region and the second semiconductor region; and
a gate electrode opposing the third semiconductor region via a gate dielectric.

10. The semiconductor device according to claim 1, wherein
the second electrode comprises aluminum,
the metal silicide layer comprises nickel silicon (NiSi), and
the metal layer comprises titanium.

11. The semiconductor device according to claim 1, wherein a shape of a bottom surface of the metal layer is a projection shape so as to closely adhere to an inner periphery surface of the recess of the metal silicide layer.

12. The semiconductor device according to claim 11, wherein an upper surface of the metal layer is recessed along a shape of the recess of the metal silicide layer.

13. The semiconductor device according to claim 12, wherein a bottom surface of the second electrode contacting the metal layer is in a projection shape along a recess of the metal layer.

14. The semiconductor device according to claim 7, wherein the depth in the second portion is greater than the depth in the first portion.

15. The semiconductor device according to claim 7, wherein the depth in the first portion is greater than the depth in the second portion.

16. The semiconductor device according to claim 3, wherein
the first portion has a recessed shape recessed toward the first semiconductor region, and
the second portion has a recessed shape recessed toward the second semiconductor region.

17. The semiconductor device according to claim 5, wherein the first semiconductor region is interposed between the first portion and the second portion that are arranged along the third direction.

18. The semiconductor device according to claim 2, wherein the metal silicide layer contacts an upper surface or a side surface of the first semiconductor region.

19. The semiconductor device according to claim 3, wherein the metal silicide layer contacts an upper surface of the second semiconductor region.

20. The semiconductor device according to claim 3, wherein
the first conductive type is an n-type, and
the second conductive type is a p-type.
